(19) United States
(12) Patent Application Publication
(10) Pub. No.: US 2007/0279091 A1
(43) Pub. Date: Dec. 6, 2007

(54) Digital Voltage Level Shifter

(76) Inventors: Mayank Goel, Bangalore (IN); Prabhat Agarwal, Bangalore (IN)

Correspondence Address: Slater & Matsil, 17950 Preton Rd Suite 1000, Dallas, TX, 75252, US

(21) Appl. No.: 11/663,406

(22) PCT Filed: Sep. 22, 2004
(86) PCT No.: PCT/SG04/00308

§ 371 Date: Mar. 21, 2007

(51) Int. Cl. H03K 3/356

(52) U.S. Cl. 326/71

(57) ABSTRACT

A digital voltage level shifter for converting an input signal with a low voltage swing to an output signal with a high voltage swing comprises a first inverter stage for generating an inverted signal from an input signal, the inverted signal having a voltage swing between a core voltage and ground, and a second inverter stage for producing an anti-phase signal from the inverted input signal, the anti-phase signal having a voltage swing between the core voltage and ground. The first and second inverters each drive a respective thin gate NMOS transistor connected in cascode with a respective NMOS transistor. The sources of the first and second thin gate NMOS transistors are connected to ground. The gates of the NMOS transistors are connected to the output of the respective inverters through a respective capacitor and are referenced to the core voltage through a respective resistor. The drains of the NMOS transistors are connected to an output circuit to provide an output signal having a voltage higher than the core voltage.

### FIELD OF THE INVENTION

The present invention relates to a digital voltage level shifter for converting an input signal with a low voltage swing to an output signal with a high voltage swing.

### BACKGROUND OF THE INVENTION

In VLSI integrated circuits, particularly in the more complex circuits such as microprocessors or digital signal processors, it is often necessary to transfer signals from one voltage domain (range) to another. This may be required to be achieved at high speed and without damage to the transistors involved. The problem becomes more difficult as CMOS technology moves to lower supply voltages for the main logic of the chip, together with smaller geometries. Existing solutions generally require reference voltage supplies which must be either supplied externally or generated within the chip and therefore consume power.

In view of the foregoing problems requirements, a need exists for a method and/or system for which does not suffer from the above disadvantages.

### SUMMARY OF THE INVENTION

In general, the present invention relates to a digital voltage level shifter for converting an input signal with a low voltage swing to an output signal with a high voltage swing comprising one or more protection transistors each having a gate, wherein the drive to the gates of the one or more protection transistors is obtained from an input stage via an R-C network, the resistor in the R-C network being referenced to a predetermined voltage.

According to a first aspect of the present invention there is provided a digital voltage level shifter for converting an input signal with a low voltage swing to an output signal with a high voltage swing, the digital voltage level shifter comprising:

a first inverter stage for generating an inverted signal from an input signal, said inverted signal having an input voltage swing between a core voltage and ground;

a second inverter stage for producing an anti-phase signal from the inverted input signal, the anti-phase signal having an input voltage swing between the core voltage and ground;

said first inverter driving a first thin gate NMOS transistor connected in cascode with a first NMOS transistor, said first thin gate NMOS transistor and said first NMOS transistor each having a respective gate, source and drain;

said second inverter driving a second thin gate NMOS transistor connected in cascode with a second NMOS transistor, said second thin gate NMOS transistor and said second NMOS transistor each having a respective gate, source and drain;

said sources of the first and second thin gate NMOS transistors being connected to ground; wherein the gate of the first NMOS transistor is connected to the output of the first inverter through a first capacitor and referenced to a predetermined voltage; the gate of the second NMOS transistor is connected to the output of the second inverter through a second capacitor and referenced to the predetermined voltage; and

the drains of the NMOS transistors being connected to an output stage to provide an output signal having an output voltage swing higher than said input voltage swing.

Preferably, the gate of the first NMOS transistor is referenced to the predetermined voltage through a first resistor or a first MOS transistor; and the gate of the second NMOS transistor is referenced to the predetermined voltage through a second resistor or a second MOS transistor.

### BRIEF DESCRIPTION OF THE DRAWINGS

Embodiments of the invention will now be described, by way of example, and with reference to the accompanying drawings, in which:

FIG. 1 is a circuit diagram of a conventional system for shifting voltage signal levels to a higher range (domain); and

FIG. 2 is a circuit diagram of system according to an embodiment of the invention for shifting voltage signal levels to a higher range (domain).

### DETAILED DESCRIPTION OF PREFERRED EMBODIMENTS

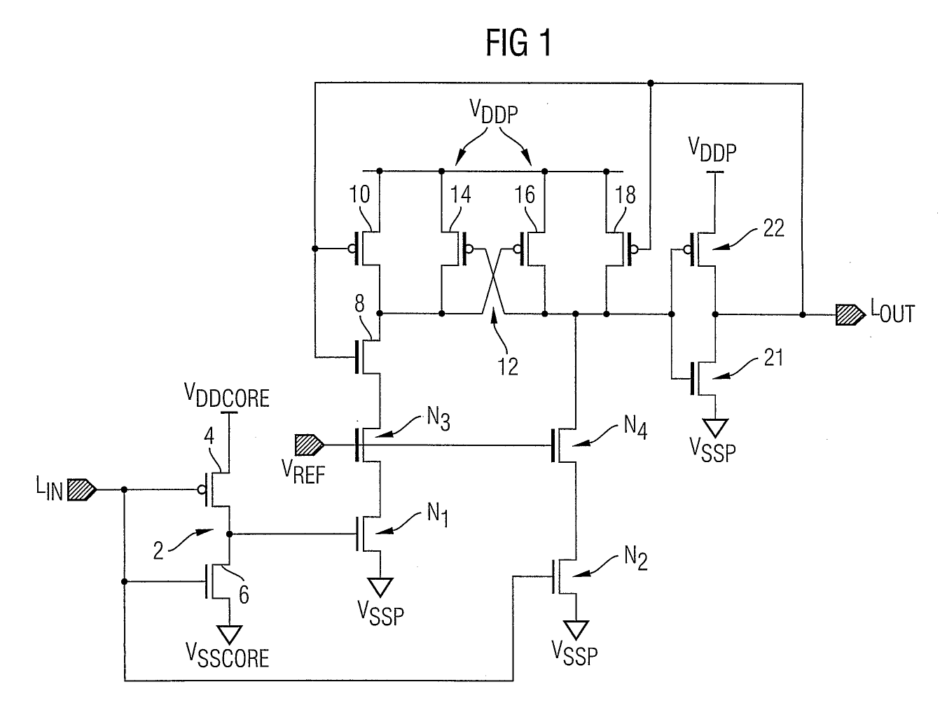

FIG. 1 shows a circuit diagram of a conventional system for shifting voltage signal levels to a higher range (domain). The system comprises an inverter stage 2 comprising two CMOS transistors 4, 6. The output of the inverter stage 2 is coupled to the gate of a thin gate NMOS transistor N1. The input signal L_{IN} is also coupled to the gate of a further thin gate NMOS transistor N2. The sources of transistors N1 and N2 are coupled to ground (V_{SSP}) and the drains of transistors N1 and N2 are coupled to the sources of two further NMOS transistors N3 and N4 respectively. The gates of transistors N3 and N4 are connected to a reference voltage V_{REF}.

The drain of N3 is connected to the source of a further transistor 8 which, together with another transistor 10, forms a second inverting stage, the output of which is coupled to a bistable circuit 12 formed by two cross-coupled transistors 14, 16. The drain of N4 is coupled to the other input to the bistable stage 12, to the drain of a further PMOS transistor 18, and also to an inverter stage 20 which is comprised of an NMOS transistor 21 and a PMOS transistor 22 connected in series. The output of the inverter stage 20 provides the output voltage L_{OUT} at the new voltage level. The output voltage L_{OUT} is applied to the gate of the transistor 18 which is connected to the drain of transistor N4 and is applied to the input to the inverter stage formed by transistors 8 and 10.

The operation of the system of FIG. 1 is as follows. The input signal L_{IN} is inverted in the inverter stage 2 and swings between the voltages V_{DDCORE}, which is the voltage of the main logic supply for the system, and V_{SSCORE} which is ground. The output of the inverter stage 2 switches transistor N1. The input signal Lin also switches transistor N2 in anti-phase to transistor N1. The sources of transistors N3 and N4 are maintained at a voltage of around (V_{REF}-V_{GS}), where V_{GS} is the threshold potential of the protection NMOS transistors N3 and N4 and V_{REF} is a reference voltage applied from an external source.

When the input signal L_{IN} is high, transistor N2 is turned on, current flows through N4 pulling the drain of transistor N4, which is the input to the inverter stage, to voltage V_{SSP} which is ground, thereby making the output L_{OUT} high.

PMOS transistors 10, 18 are not conducting when L_{OUT} is high. Also, the gate of PMOS transistor 14 is coupled to the drain of N4, which is low when L_{IN} is high, thereby making transistor 14 conduct resulting in drain of the transistor N8 rising to voltage supply level V_{DDP}. The drain of N8 is coupled to PMOS transistor 16 thereby turning it off. Also NMOS transistor 8 is conducting when L_{OUT} is high.

However, when the input signal L_{IN} is high, transistor N1 is switched off, thus there is no current path through transistors N3, 8 and 10 to V_{SSP} which is ground. In this situation, transistor N3 prevents the drain of transistor N1 from rising above (V_{REF}-V_{GS}), thus protecting transistor N1 from damage due to gate-oxide stress.

When the input signal L_{IN} changes from high to low, transistor N1 turns on, transistor N2 switches off and there is no current path through transistors N4 and N2. As transistor N1 turns on, current flows through transistors 8, N3 and 10, thereby pulling the drain of transistor 8 to voltage level V_{SSP}, which is ground, thereby making PMOS transistor 16 conducting and pulling the drain of transistor N4 to voltage supply level V_{DDP}, which is the input to the inverter stage 20. The output of the inverter stage 20, L_{OUT}, is pulled down to voltage V_{SSP}, which is ground.

In this condition, when L_{IN} is low and L_{OUT} is low, PMOS transistor 18 conducts and holds the input to the inverter stage 20 to voltage supply level V_{DDP}. Transistor N4 prevents the drain of N2 from rising above (V_{REF}-V_{GS}) thereby protecting N2 from damage due to gate-oxide stress. Also, transistor 8 switches off when L_{OUT} is low, disabling the current path through transistors 8, N3 and N1 to V_{SSP} which is ground. PMOS transistor 10, the gate of which is coupled to the output of inverter stage 20, conducts and pulls the drain of the transistor 8 up to the voltage supply level V_{DDP}.

V_{REF} has the value equal to the sum of the smaller voltage V_{DDPCORE} of the main logic supply for the system plus the threshold potential V_{GS} of the protection NMOS transistors N3 and N4. Thus, transistors N3 and N4 protect the transistors N1 and N2 from damage due to gate oxide stress.

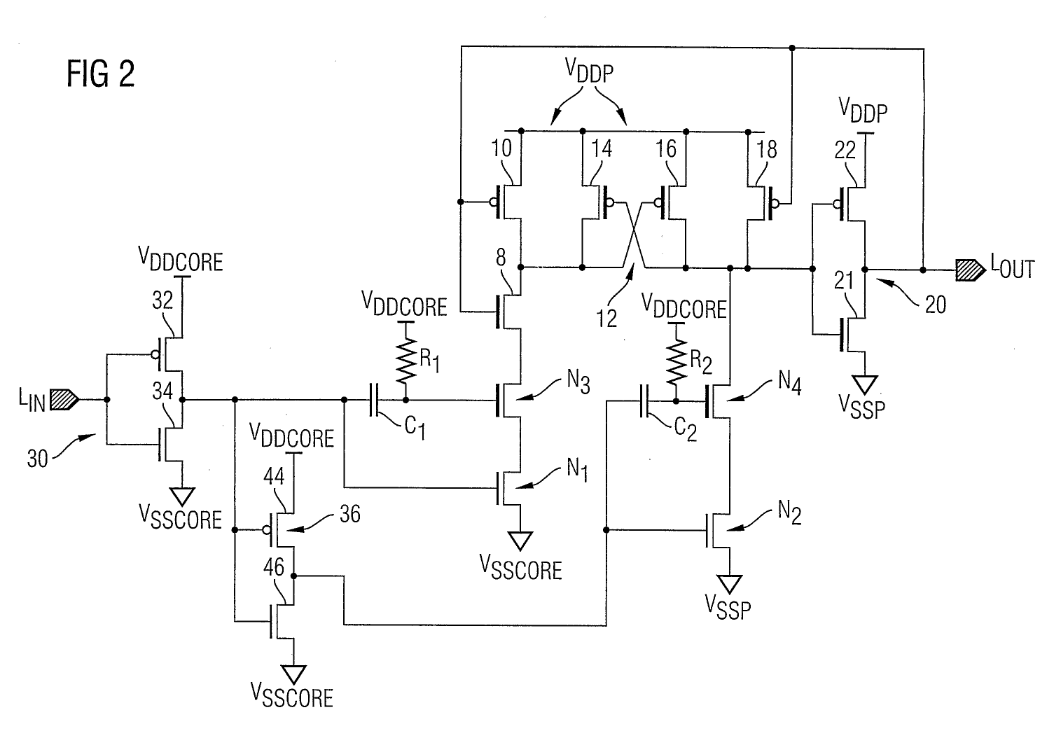

FIG. 2 shows a circuit diagram of system according to an embodiment of the invention for shifting voltage signal levels to a higher range (domain). The input signal L_{IN} is fed to an inverter 30 comprising two transistors 32, 34 which drives a further inverter 36. The outputs of the inverters 30, 36 are coupled to the gates of two transistors N1 and N2 respectively. The sources of two protection NMOS transistors N3 and N4 are connected to the drains of the two transistors N1 and N2 respectively. The gate of the transistor N3 is coupled to the inverted signal from the inverter stage 30 via a high-pass network comprising a capacitor C1 and a resistor R1 and is referenced to V_{DDCORE} through resistor R1. The signal from the inverter 30 swings between a voltage V_{DDCORE}, which is voltage of the main logic supply for the system, and ground (V_{SSCORE}). In a preferred embodiment, the voltage V_{DDCORE} is around 0.9 Volts.

Similarly, the gate of transistor N4 is referenced to the voltage V_{DDCORE} via a resistor R2 which, with a capacitor C2, forms a high-pass network, the further side of C2 being coupled to the output of the inverter 36.

In this embodiment, the inverter stage 36 comprises two CMOS transistors 44, 46. The output of inverter 36 is coupled to the gate of transistor N2. The sources of transistors N1 and N2 are coupled to ground (V_{SSP}) and the drains of transistors N1 and N2 are coupled to the sources of two further NMOS transistors N3 and N4 respectively.

The drain of transistor N3 is connected to the source of a further transistor 8 which, together with another transistor 10, forms a further inverting stage, the output of which is coupled to a bistable circuit 12 formed by two cross-coupled transistors 14, 16. The drain of transistor N4 is coupled to the other input to the bistable stage 12, to the drain of a further PMOS transistor 18, and also to an inverter stage 20 which is comprised of an NMOS transistor 21 and a PMOS transistor 22 connected in series. The output of the inverter stage 20 provides the output at the new voltage level L_{OUT}.

The output voltage L_{OUT} is applied to the gate of the transistor 18 connected to the drain of the transistor N4 and to the input to the inverter stage formed by transistors 8 and 10.

The operation of the system of FIG. 2 is as follows. The input signal L_{IN} is inverted in the inverter stage 30 and swings between the voltages V_{DDCORE} and V_{SSCORE}. The output of the inverter stage 30 switches transistor N1. The output of the inverter 30 is further inverted in the inverter 36 and switches transistor N2 in anti-phase to transistor N1. The sources of transistors N3 and N4 are maintained at a voltage of approximately (V_{DDCORE}-V_{GS}), where V_{GS} is the threshold potential of the protection NMOS transistors N3 and N4.

Thus, when the output of the inverter 30 rises positively, the gate of transistor N3 rises by an amount equal to around (V_{DDCORE}-V_{SSCORE}). By selection of the values of the components C1 and R1, this provides the shift voltage and protection required without the need for an external reference voltage.

Similarly, when L_{IN} rises, the output of inverter stage 36 will also rise turning transistor N2 on and driving the gate of transistor N4 positively via capacitor C2 and resistor R2 thus providing the required shift voltage and protection without the need for an external reference voltage.

When the input signal L_{IN} is high, transistor N2 is turned on, current flows through N4 pulling the drain of transistor N4, which is the input to the inverter stage, to voltage V_{SSP} which is ground, thereby making the output L_{OUT} high.

PMOS transistors 10, 18 are not conducting when L_{OUT} is high. Also, the gate of PMOS transistor 14 is coupled to the drain of N4, which is low when L_{IN} is high, thereby making transistor 14 conduct resulting in drain of the transistor N8 rising to voltage supply level V_{DDP}. The drain of N8 is coupled to PMOS transistor 16 thereby turning it off. Also NMOS transistor 8 is conducting when L_{OUT} is high. In a preferred embodiment, V_{DDP} is around 2.5 Volts.

However, when the input signal L_{IN} is high, transistor N1 is switched off, thus there is no current path through transistors N3, 8 and 10 to V_{SSP} which is ground. In this situation, transistor N3 prevents the drain of transistor N1 from rising above (V_{DDCORE}-V_{GS}), thus protecting transistor N1 from damage due to gate-oxide stress.

When the input signal L_{IN} changes from high to low, transistor N1 turns on, transistor N2 switches off and there is no current path through transistors N4 and N2. As transistor N1 turns on, current flows through transistors 8, N3 and 10, thereby pulling the drain of transistor 8 to voltage level V_{SSP}, which is ground, thereby making PMOS transistor 16 conducting and pulling the drain of transistor N4 to voltage supply level V_{DDP}, which is the input to the inverter stage 20. The output of the inverter stage 20, L_{OUT}, is pulled down to voltage V_{SSP}, which is ground.

In this condition, when L_{IN} is low and L_{OUT} is low, PMOS transistor 18 conducts and holds the input to the inverter stage 20 to voltage supply level V_{DDP}. Transistor N4 prevents the drain of N2 from rising above (V_{DDCORE}-V_{GS}) thereby protecting N2 from damage due to gate-oxide stress. Also, transistor 8 switches off when L_{OUT} is low, disabling the current path through transistors 8, N3 and N1 to V_{SSP} which is ground. PMOS transistors 10, the gate of which is coupled to the output of inverter stage 20, conducts and pulls the drain of the transistor 8 up to the voltage supply level V_{DDP}.

In summary, if either of the protection transistors N3 or N4 are turned off, the drain at that transistor is pulled to the higher voltage level V_{DDP} and the voltage at the gate of the transistor connected to the drain of that transistor goes to V_{SSP}, thus setting the conditions of the bistable stage 12 so that the output line is pulled between a high level, namely V_{DDP}, and V_{SSP} thereby enabling a high level voltage swing.

In a further preferred embodiment, resistors R1 and R2 may be omitted and replaced by MOS transistors which are kept in the ON state. The operation of the system according to this embodiment is the same as that described above with reference to FIG. 2.

The systems and methods according to the present invention may be particularly useful in devices having very low core voltages and to provide high speed protection to the low voltage transistors in the circuit from damage due to gate oxide stress. A quick voltage shift may be achieved without the requirement for an external reference voltage, and without static power dissipation.

Various modifications to the embodiments of the present invention described above may be made. For example, other components and method steps can be added or substituted for those above. Thus, although the invention has been described above using particular embodiments, many variations are possible within the scope of the claims, as will be clear to the skilled reader, without departing from the spirit and scope of the invention.

1-12. (canceled)

13. A digital voltage level shifter to convert an input signal with an input voltage swing to an output signal with an output voltage swing, the digital voltage level shifter comprising:
a first transistor of a first category connected in cascade with a first transistor of a second category, the first transistor of the first category and the first transistor of the second category each having a respective gate, source and drain;
a second transistor of the first category connected in cascade with a second transistor of the second category, the second transistor of the first category and the second transistor of the second category each having a respective gate, source and drain;
the sources of the first transistor of the first category and second transistor of the first category being connected to ground;
the gate of the first transistor of the second category being connected to an input through a first capacitor and referenced to a predetermined voltage;
the gate of the second transistor of the second category being connected to the input through a second capacitor and referenced to the predetermined voltage; and
the drains of the first transistor of the second category and second transistor of the second category being connected to an output stage to provide the output signal, with the output voltage swing higher than the input voltage swing.

14. A digital voltage level shifter according to claim 13, wherein the first transistor of the first category is a first thin gate NMOS transistor, the second transistor of the first category is a second thin gate NMOS transistor, the first transistor of the second category is a first NMOS transistor, and the second transistor of the second category is a second NMOS transistor.

15. A digital voltage level shifter according to claim 13 further comprising a first stage for generating a first signal from the input signal, the first capacitor being connected to an output of the first stage.

16. A digital voltage level shifter according to claim 15 further comprising a second stage for producing a second signal from the first signal, the second capacitor being connected to an output of the second stage.

17. A digital voltage level shifter according to claim 14, wherein the gate of the first NMOS transistor is referenced to the predetermined voltage through a first resistor; and the gate of the second NMOS transistor is referenced to the predetermined voltage through a second resistor.

18. A digital voltage level shifter according to claim 16, wherein the first stage and second stage each comprises inverters, each inverter having an NMOS transistor and a PMOS transistor connected in series, the source of each NMOS transistor being connected to ground and the source of each PMOS transistor being connected to a core voltage supply, the gate of the NMOS transistor being connected to the gate of the PMOS transistor, and the drain of the NMOS transistor being connected to the drain of the PMOS transistor.

19. A digital voltage level shifter according to claim 18, wherein the core voltage supply is around 0.9 Volts.

20. A digital voltage level shifter according to claim 13, wherein the output signal has a voltage of around 2.5 Volts.

21. A digital voltage level shifter according to claim 14, wherein the first thin gate NMOS transistor and the second thin gate NMOS transistor are low voltage transistors.

22. A digital voltage level shifter according to claim 14, wherein the first NMOS transistor and second NMOS transistor are high voltage transistors.

23. A digital voltage level shifter according to claim 18, wherein the output stage comprises a third inverter connected to the drain of the first NMOS transistor, the third inverter comprising a PMOS transistor having a source connected to a voltage supply higher than the core voltage, the source of the NMOS transistor in the third inverter being connected to the drain of the first NMOS transistor, the gates of the NMOS and PMOS transistors in the third inverter being connected to an output of the output stage.

24. A digital voltage shifter according to claim 23, wherein the output of the third inverter is coupled to an input of a pair of cross-coupled PMOS transistors forming a bi-stable stage, the sources of the PMOS transistors being connected to the voltage supply, the drain of the second NMOS transistor being connected to a further input of the bi-stable pair of transistors and to a fourth inverter, the fourth inverter providing the output signal, the fourth inverter operating between ground and the voltage of the voltage supply to provide the output voltage swing.

25. A digital voltage level shifter according to claim 24, wherein the output stage further comprises a further PMOS transistor connected between the drain of the second NMOS transistor and the high voltage supply, its gate being connected to the output of the output stage.

26. A digital voltage level shifter according to claim 18, wherein the predetermined voltage is the core voltage.

27. A digital voltage level shifter according to claim 14, wherein the gate of the first NMOS transistor is referenced to the predetermined voltage through a first MOS transistor; and the gate of the second NMOS transistor is referenced to the predetermined voltage through a second MOS transistor.
